(19) United States
(12) Patent Application Publication
(10) Pub. No.: US 2014/0176615 A1
(43) Pub. Date: Jun. 26, 2014

(54) TRANSPARENT DISPLAY USING SELECTIVE LIGHT FILTERING

(71) Applicants: UYGAR E. AVCI, Portland, OR (US); MICHAEL C. MAYBERRY, Beaverton, OR (US)

(72) Inventors: UYGAR E. AVCI, Portland, OR (US); MICHAEL C. MAYBERRY, Beaverton, OR (US)

(21) Appl. No.: 13/726,412

(22) Filed: Dec. 24, 2012

(51) Int. Cl. G02F 1/15; G09G 5/10; H01L 33/58

(52) U.S. Cl. CPC G02F 1/15; H01L 33/58; G09G 5/10
USPC 345/690; 359/265; 438/29

(57) ABSTRACT

A transparent display device and method of forming such device. The transparent display device includes a substrate, wherein the substrate allows greater than 50% of incident light to pass through the substrate. The device also includes a plurality of pixels formed on the substrate, wherein the pixels are formed of an adjustable permittivity material wherein the adjustable permittivity material exhibits a change in permittivity upon the application of a voltage and is normally transparent. The device further includes interconnects operatively coupled to the adjustable permittivity material in each pixel, wherein the interconnects are configured to provide voltage to the adjustable permittivity material.

### FIELD

The present disclosure relates to providing a transparent display that uses selective light filtering for generating images.

### BACKGROUND

Consumer devices, such as cell phones, televisions, computer monitors, etc, are ubiquitous. These devices are typically quite visible in the surrounding environment and often block the view of the environment behind them. Take, for example, the case of cell phones. Often cell phone users hold their phone up to view the screen, while walking or performing other tasks. However, this blocks the view of the environment behind the phone, such as the side walk, the busy street or children playing at the park. Or consider a television screen, which generally blocks the view of everything behind it, such as a wall or the other side of a room. While efforts have been made to reduce the foot print of some of these consumer devices, in the case of televisions for example, larger screens are commonly more desirable. Accordingly, there remains room for improvement in blending consumer devices into the environment, or at least, allowing the user to see the environment behind the device.

Furthermore, many of these devices and, particularly LCD devices, utilize a backlight in their displays. However, such use of a backlight significantly drains battery power, as compared to performing other functions. Accordingly, there remains room for improvement in reducing power drain caused by backlight technology.

### BRIEF DESCRIPTION

The above-mentioned and other features of this disclosure, and the manner of attaining them, may become more apparent and better understood by reference to the following description of embodiments described herein taken in conjunction with the accompanying drawings, wherein:

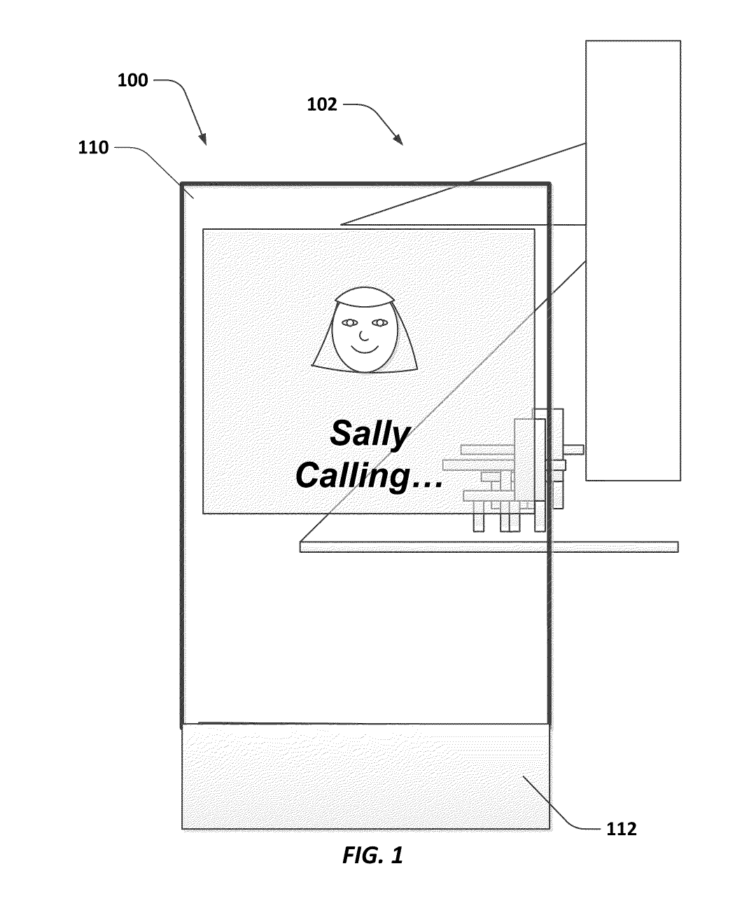

FIG. 1 illustrates an embodiment of a display described herein.

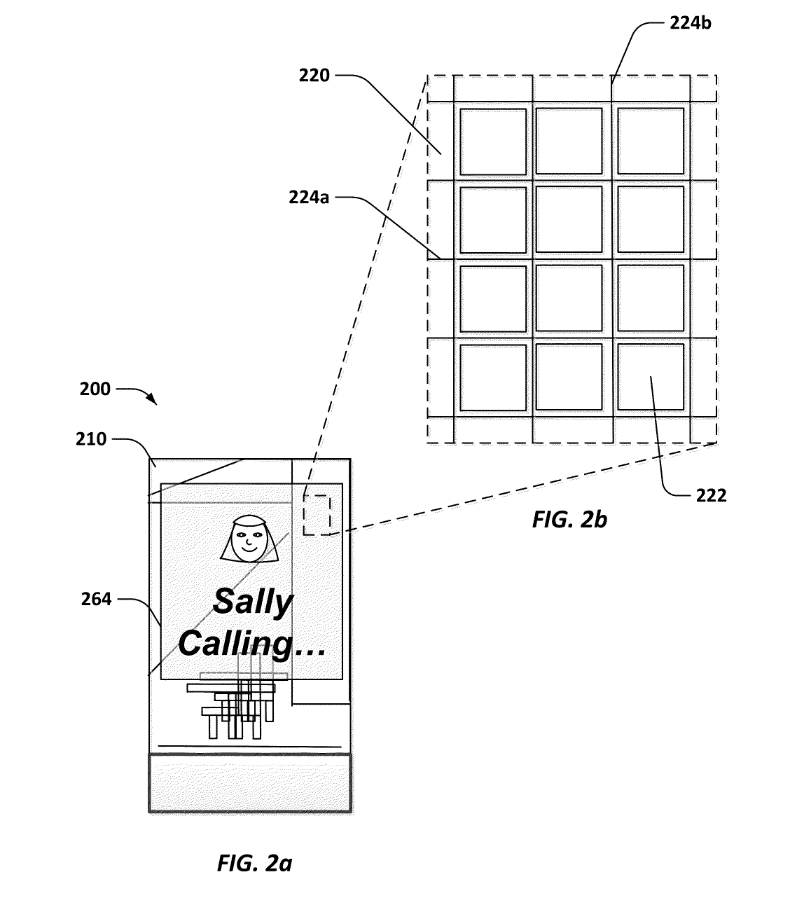

FIG. 2a illustrates an embodiment of a display described herein and

FIG. 2b illustrates a close-up view of the display of FIG. 2a.

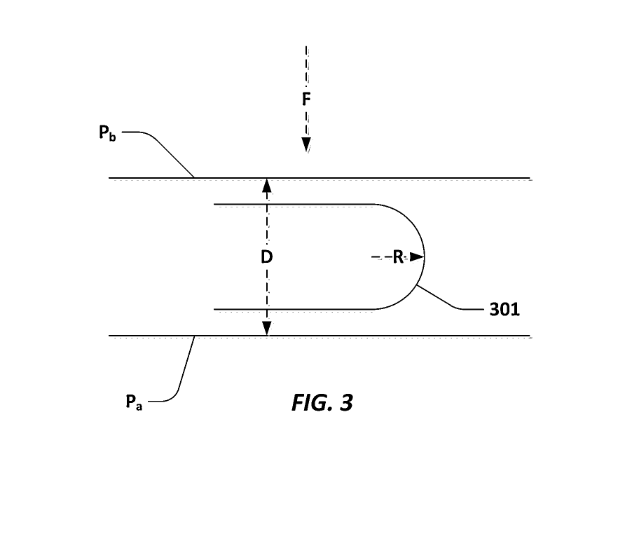

FIG. 3 illustrates a schematic diagram of an embodiment of performing a bend radius test.

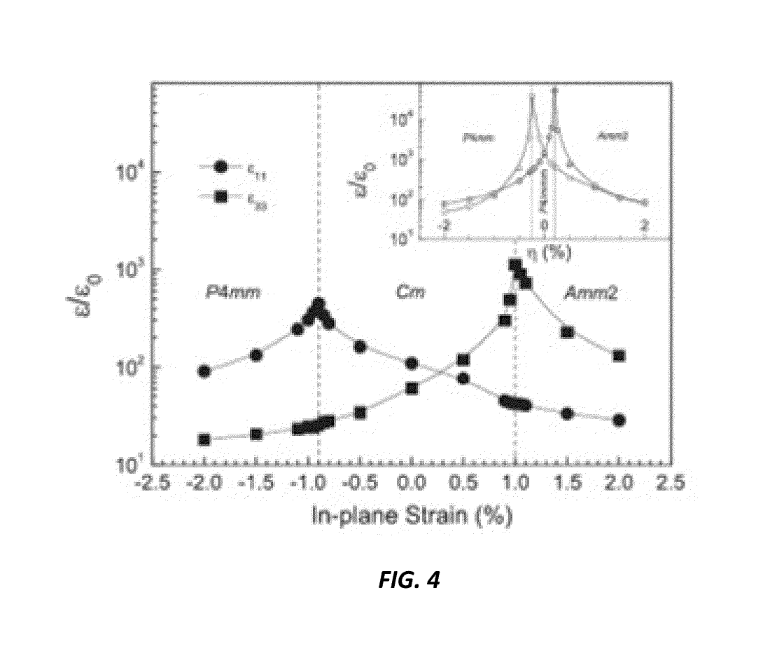

FIG. 4 illustrates the effect of strain on the relative permittivity of BTO. Specifically, the in-plane (E11) and out-of-plane (E33) dielectric constants of BaTiO₃ are illustrated at various misfit strains. The inset shows the components of the dielectric constant in SrTiO₃, another non-limiting example of an adjustable permittivity material, as a function of the misfit strain. The square and circle symbols denote E33 and E11, respectively.

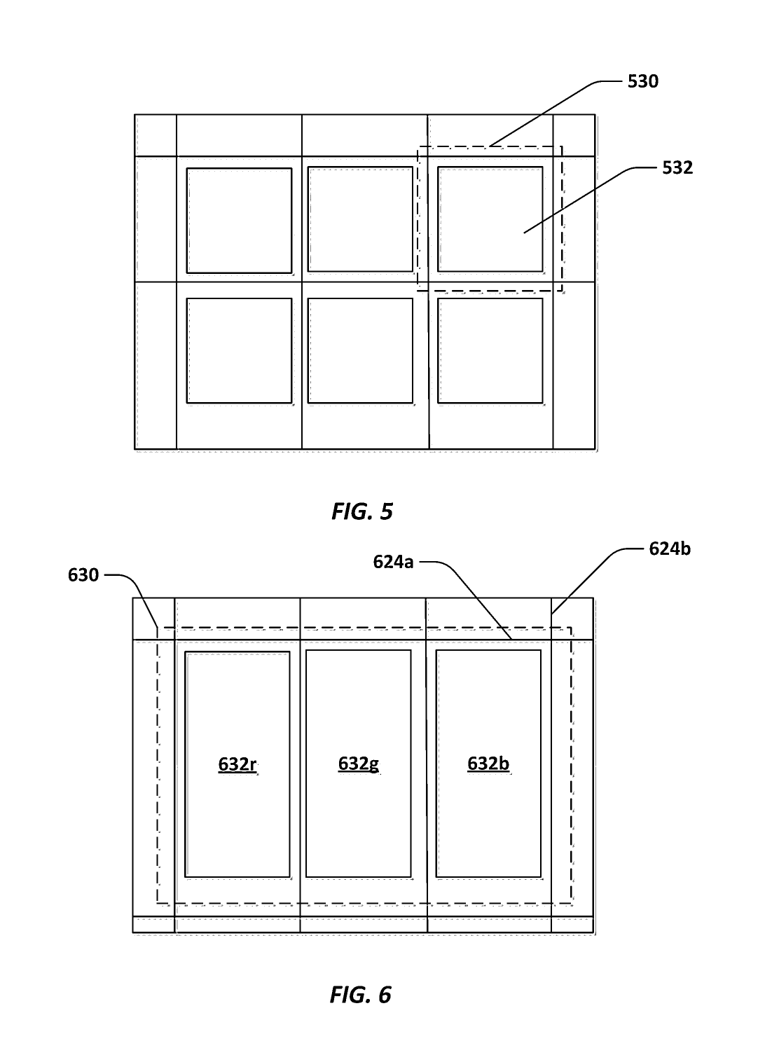

FIG. 5 illustrates an embodiment of a display described herein including pixels, each pixel being formed of a single element.

FIG. 6 illustrates an embodiment of a display described herein including pixels, each pixel being formed of three elements.

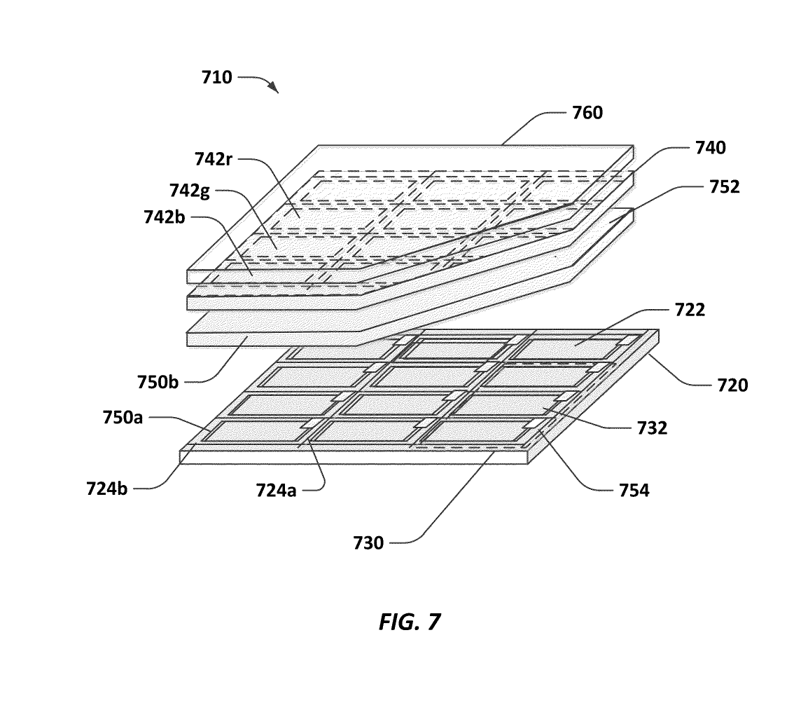

FIG. 7 illustrates an embodiment of a display described herein including a color mask, source and drain electrodes and transistors for controlling the display.

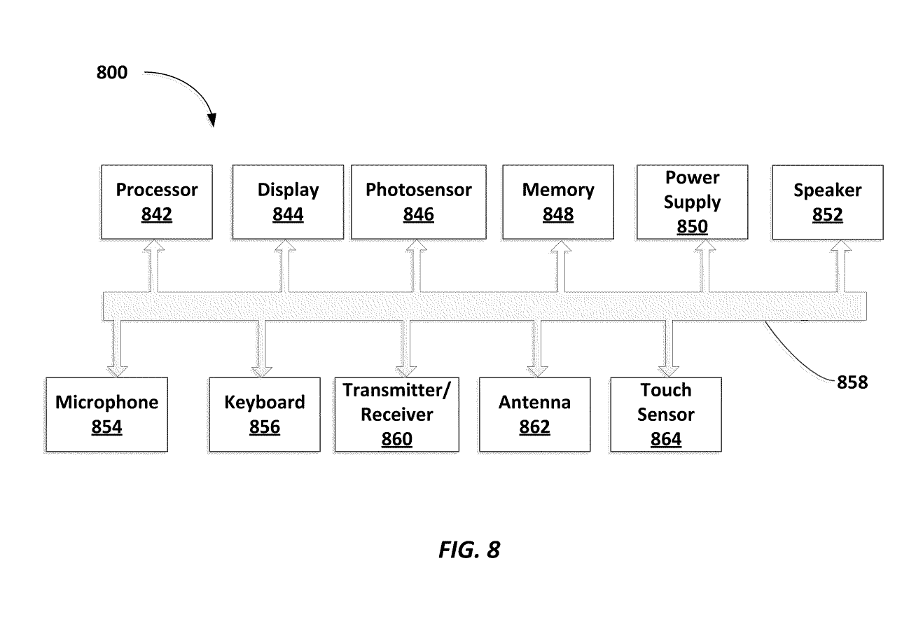

FIG. 8 illustrates an embodiment of a system for generating images on the display described herein.

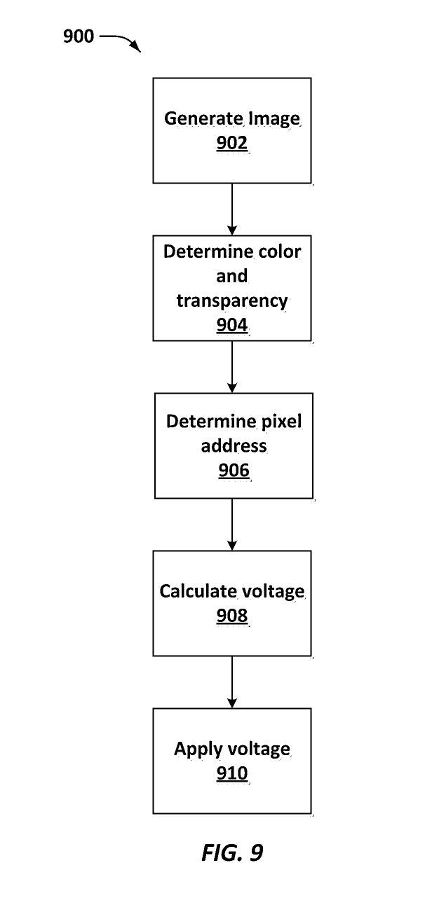

FIG. 9 illustrates an embodiment of a method for generating images on the display described herein.

### DETAILED DESCRIPTION

The present disclosure relates to providing a transparent display that uses selective light filtering for generating images and a method of forming such display. The display does not require, and in embodiments, does not include, a back light or other light generating mechanisms within the device to create the visual image. Further, due to the transparency aspect of the display, safety in using the device may be improved as the user is able to see what is behind the device during use, preventing accidents or other mishaps, particularly if the device is used in urban environments while moving. In eliminating the light, the battery consumption can be reduced in embodiments. While mobile devices are discussed in embodiments herein, the display can be incorporated into other electronic devices as well, such as display screens including television screens and computer monitors, as well as electronically modified windows.

FIG. 1 illustrates an embodiment of a transparent display 110 incorporated in a mobile device 100, such as a mobile phone or tablet. When the display is inactive, or off, it is in the normally transparent mode and allows at least 50% of incident light having a wavelength in the range of 380 nm to 700 nm, including all values and ranges therein, to pass through the display. For example, from 50% to 99% of incident light passes through the display, from 60% to 90%, 75%, etc. Thus, one may see the environment 102 behind the phone through the phone display. The electronics that operate the device 100 are housed in a portion of the device (the housing 112) that, in embodiments, is opaque wherein less than 50% of incident light having a wavelength in the range of 380 nm to 700 nm, including all values and ranges therein passes through. Alternatively, the housing for the electronics is transparent.

In embodiments, the display forms monochrome images, color images or combinations thereof with or without the use of a backlight. To achieve desired colors and various images, the display may use a number of pixels, including sub-elements formed from an adjustable permittivity material. In embodiments, adjusting the permittivity of the adjustable permittivity material provides various colors based on a color model, such as an additive color model (RGB) or a subtractive color model (CMYK), described further herein. Alternatively, or in addition, various colors are achieved using single pixel elements, wherein altering the permittivity of an adjustable permittivity material achieves the desired color outside of the bounds of a given additive or subtractive color model. Altering the permittivity of the material alters the refractive index of the material and other characteristics such as transparency, i.e., the total amount of incident light that passes through the material, or translucency, i.e., the amount of incident light scattered in the material.

With this in mind, rather than activating substantially all of the pixels on a display, in embodiments, application developers may elect to display only selected information when formulating instructions for generating images on the display such that the user may be able to view objects behind the display. For example, in the case of an application related to making telephone calls, the display only displays the caller's identity and a related photograph, leaving the remainder of the pixels transparent so that the user of the device can view what is behind the device. In the case of a street map application, the developer may elect to display only the streets and street names, the area between the streets may be left transparent. Or, in the case of a calendar application, only the numbers and calendar lines may be displayed and the remaining pixels may be left transparent.

In embodiments as illustrated in FIGS. 2a and 2b (a close-up of FIG. 2a), the display 210 of the device 200 generally includes a transparent substrate 220, adjustable permittivity material 222 deposited onto the substrate 220, horizontal interconnects 224a and vertical interconnects 224b operatively coupled to the adjustable permittivity material for applying a voltage to the adjustable permittivity material 222 to adjust its permittivity. Operative coupling is understood herein to provide electrical contact between the interconnects and the adjustable permittivity material, so that a voltage can be provided to the adjustable permittivity material through the interconnects. This can be done with conventional back-end interconnect processing techniques.

In addition, as the interconnects cover a significantly small percentage of the total area, and in embodiments are from 5 nm to 100 μm in thickness, including all values and ranges therein. they do not prevent the device to look transparent to human eye. In addition, the display optionally includes a touch sensitive portion 264.

The transparent substrate 220 includes a glass or polymer material. Examples of glass include, for example, flexible glass such as WILLOW GLASS available from CORNING. Examples of polymer materials include polyethylene terephthalate (PET), polyether ether ketone (PEEK), polycarbonate, etc. Again, transparent is understood as allowing at least 50% of incident light to pass through the substrate material, having one or more wavelengths in the range of 380 nm to 700 nm, including all values and ranges therein. Thus, up to 99% of light may pass through the transparent substrate, or from 50% to 99% of the incident light, including 60%, 75%, 80%, etc. In embodiments, the transparent substrate exhibits a thickness in the range of 0.1 mm to 2 cm, including all values and ranges therein, such as 1 mm to 1 cm, 5 mm, etc.

Additionally, in embodiments, the transparent substrate 220 is relatively flexible and exhibits a bending radius of 5 cm or less, including all values and ranges from 0.1 mm to 5cm. including 0.2 mm to 2.0 cm, etc. Bending radius, or radius of bending, is understood as the minimum radius the substrate can be bent without damage. In embodiments, bending radius is measured as illustrated in FIG. 3. A sample 301 is loaded between two parallel plates Pₐ, P_{b} and a force (F₁) is applied to the plates reducing the distance (D) between the plates. As the plates approach one another the bending radius (R) is reduced. The smaller the bending radius achieved prior to material failure, the more relatively flexible the material is. In addition, or alternatively, the electrical substrate exhibits a flexural modulus of 30 GPa or less, including all values and ranges between 0.1 to 30 GPa. Such as less than 20 GPa, in the range of 0.1 GPa to 15 GPa, 0.04 GPa to 1.0 GPa, 8 GPa to 10 GPa, etc. The flexural modulus may be measured using ASTM D790-10.

Referring again to FIG. 2b, the adjustable permittivity material 222 includes a piezoelectric material that, upon application of a voltage, an internal mechanical strain is generated and the relative permittivity, i.e., the dielectric constant εr, is altered. For example, the material may be adjusted from a normally transparent state to a color state or mode, wherein the user perceives that a given color of a given transparency is displayed on the screen. Piezoelectric materials are understood to exhibit a linear electromechanical interaction, i.e., providing an internally generated charge upon the application of a mechanical force or, inversely, providing an internally generated mechanical strain upon the application of an electrical field. Permittivity is understood herein as a measure of a material's ability to resist the formation of an electric field within it and, in the adjustable permittivity materials described herein, is known to change upon the application of a strain. And relative permittivity is understood as the ratio of the amount of electrical energy stored in a material by an applied voltage, relative to that stored in a vacuum. Relative dielectric constant, εᵣ, is understood as the relatively permittivity of a material, the ratio of its permittivity to permittivity of vacuum. In addition, as understood herein, refractive index is approximately the square root of the relative permittivity.

Thus, without being bound to any particular theory, generating an internal mechanical stress and altering the permittivity of the adjustable permittivity material alters the refractive index. The application of a voltage, therefore, affects the transparency of the material and the color of the light that is transmitted through the material. Such relationships between the permittivity, strain and voltage are measured and employed to determine the voltage to apply to the material to achieve a desired effect.

Further, the adjustable permittivity material is normally transparent and is understood as allowing at least 50% of incident light to pass through the substrate material, having one or more wavelengths in the range of 380 nm to 700 nm, including all values and ranges therein, when a voltage is not applied to the material. Thus, up to 99% of light may pass through the transparent substrate, or from 50% to 99% of the incident light, including 60%, 75%, 80%, etc.

In embodiments, the adjustable permittivity materials 222 include perovskite compounds having the formula: ABX₃, which demonstrate a change in permittivity upon the application of a voltage. A is a cation of a first size S₁ and B is a cation of a second size S₂, which is smaller than the cation of A (i.e., S₁>S₂). X is an anion that bonds to both cations and is oxygen. In addition, the adjustable permittivity material may be doped with, for example, nickel oxide, aluminum, lanthanum or other compounds, altering the dielectric constant.

Barium titanate (BTO), having the formula: BaTiO₃, is a non-limiting example of an adjustable permittivity material. The dielectric constant εᵣ of BTO is in the range of 1250 to 10,000 depending on temperature, orientation and doping. FIG. 4 illustrates the effect of strain on the relative permittivity of BTO. Specifically, the in-plane (E11) and out-of-plane (E33) dielectric constants of BaTiO₃ are illustrates at various misfit strains. The inset shows the components of the dielectric constant in SrTiO₃, another non-limiting example of an adjustable permittivity material, as a function of the misfit strain. The square and circle symbols denote E33 and E11, respectively. A further non-limiting example of an adjustable permittivity material is barium strontium titanate (BST), having the chemical formula: [BaₓSr₁₋ₓ]TiO₃, wherein 0≦x≦1, including all values and ranges therein, such as 0<x<1, x=0.7, x=0.5, x=0.3, etc. Yet another non-limiting example of an adjustable permittivity material is lead zirconate titanate (PZT), having the formula: Pb[ZrₓTi₁₋ₓ]O₃, wherein 0≦x≦1, including all values and ranges therein such as 0<x<1, x=0.3, x=0.7, etc. The dielectric constant Er of PZT can range from 300 to 3850 depending upon orientation and doping. Other non-limiting examples include SrTiO₃; (PbSr)TiO₃, (PbCa)TiO₃, Ba(TiSn)O₃, Ba(TiZr)O₃ and KTaO₃.

In embodiments, the adjustable permittivity material is deposited at a thickness in the range of 10 nm to 100 μm, including all values and range therein. Lithography is performed using techniques such as photolithography, electron beam lithography or ion beam lithography. In addition, or alternatively, deposition techniques such as sol gel or physical vapor deposition, including RF sputtering or pulsed laser deposition, are used.

The interconnects 224a, 224b are also applied to the substrates using a number of process techniques, such as lithography, chemical vapor deposition, physical vapor deposition, etc. In particular, interconnect materials may include, for example, a transparent conductive oxide such as indium tin oxide (ITO) or indium-doped zinc oxide, silver, gold, graphene, single walled carbon nanotubes (SWNT), calcium, aluminum, gallium, inherently conductive polymers such as polyaniline, polythiophene, and poly(3,4-ethylenedioxythiophene) poly(styrenesulfonate) (PEDOT:PSS), and combinations thereof. Each interconnect is formed from the same materials, different materials or combinations of materials.

In embodiments, the adjustable permittivity material is deposited on the substrate as a series of discrete regions or pixels, i.e., the smallest addressable element in a display device, wherein the address of the pixel corresponds to its physical location. In embodiments, the pixels include one or more sub-pixels or elements, including all values and ranges from 1 to 10 elements, including all values and ranges therein, such as 1 element, 3 elements, 4 elements, etc. Again, the elements are formed of discrete regions of the adjustable permittivity material. As discussed below, when more than one element is present, each of the elements corresponds, e.g., to a selected color in a color model. The pixels exhibit a length of 10 μm to 500 μm, including all values and ranges therein, such as in the range of 100 μm to 200 μm, 150 μm, 175 μm, 250 μm, 300 μm, etc. The pixels also exhibit a width of 10 μm to 500 μm, including all values and ranges therein, such as in the range of 100 μm to 200 μm, 150 μm, 175 μm, 250 μm, 300 μm, etc. Furthermore, the pixel density is in the range of 100 pixels per inch to 1000 pixels per inch, including all values and ranges therein.

FIG. 5 illustrates one embodiment wherein a single element 532 of the adjustable permittivity material is present in a pixel 530, where upon the application of a voltage the thickness and permittivity/dielectric constant of the adjustable permittivity material is altered. This changes the refractive index and therefore, the wavelength of the light passing through the display. Accordingly, the single element is sufficient, in such an embodiment to create, for example, red, green or blue, as well as a variety of other colors.

In another embodiment, illustrated in FIG. 6, wherein an additive color model is used, multiple elements 632r, 632g, 632b, form a single pixel 630 including, for example, a red element 632r, a green element 632g and a blue element 632b, which are transparent without the application of a voltage. As illustrated, the horizontal interconnects 624a and vertical interconnects 624b pass between and supply a voltage to each element. Upon the application of a voltage, the thickness, permittivity, or a combination of both thickness and permittivity of the elements are changed causing the pixel to display different degrees of red, blue and green each on a scale of 0 to 100. The three elements may be formed of a single adjustable permittivity material or multiple adjustable permittivity materials, which may or may not be doped. In other embodiments, wherein a subtractive color model is used 4 pixels are present.

FIG. 7 illustrates an embodiment, wherein an optional color mask 740, such as a red-green-blue color mask, is employed in the display 710 overlying the adjustable permittivity material forming the elements of the pixels. In embodiments, the color mask is formed as a film and positioned over the adjustable permittivity material. In other embodiments, the color mask is deposited directly on the adjustable permittivity material. Adjusting the permittivity of the adjustable permittivity material 722 changes the transmission rate and transparency of the light and the color mask defines its color. Again, the display includes a number of pixels 730, which include multiple sub-elements 732 per pixel. The sub-elements 732 are registered with corresponding color locations in the color mask 740, such as red 742r, green 742g, blue 742b and combinations thereof in the color mask 740.

In this embodiment, which may be combined with any of the above embodiments, horizontal 724a and vertical interconnects 724b are connected to a supply electrode 750a for each pixel and a drain electrode 750b provided for one or more pixels 730. The supply electrode 750a, in embodiments, is deposited between the substrate 720 and the adjustable permittivity material 722 and operatively coupling at least one of the vertical and horizontal interconnects to the adjustable permittivity material. The drain electrode 750b is deposited over the adjustable permittivity material 722 or on a carrier 752 and contacted, directly or indirectly, with the adjustable permittivity material 722 opposite to said substrate. Furthermore, transistors 754, such as thin film transistors, are optionally operatively coupled to each pixel element 732 and one or more of the interconnects 724a, 724b to act as a switch and apply voltage to the adjustable permittivity material 722 of a given pixel 730, or pixel sub-elements 732. Similarly, various capacitors may also be present.

In embodiments, a protective layer 760, or upper substrate is provided directly or indirectly adjacent to the adjustable permittivity material to prevent or reduce damage occurring to the various components of the display device, including the substrate, adjustable permittivity material, interconnects, electrodes or combinations thereof. The protective layer is likewise formed of a transparent material, such as acrylic, polycarbonate, polyester terephthalate, etc. The protective layer directly or indirectly covers at least the adjustable permittivity material opposing the substrate and, in other embodiments, covers the entire display including the substrate. In embodiments, polarizers, such as those found in LCD screens, are not provided.

In an embodiment illustrated in FIG. 8, the device 800 employs a system 840 for forming and displaying images. The system 840 generally includes a processor 842, the display 844, memory 848, a power supply 850, as well as optionally, various user interfaces, such as photosensors 846, speaker 852, microphone 854, keyboard 856, battery and various I/O components, etc. The various components are connected via a system bus 558. The system bus is selected from, for example, a local bus, a peripheral bus, a memory bus or memory controller, using any variety of bus structures. While a single, central bus is illustrated, other alternative bus designs, including multiple busses can be utilized as well. In addition, in embodiments, a transceiver, receiver, transmitter or combinations thereof (collectively 860) is present and configured to provide communication via various communication protocols and standards, such as BLUETOOTH®, WI-FI® IEEE 802.11, Global System for Mobile Communications (GSM), Interim Standard 95, CDMA2000, LTE Advanced, etc. Furthermore, an antenna is present 862. In embodiments, a portion of the display is touch sensitive including a touch sensor 864 such as a capacitance sensor, resistive sensor, surface acoustic wave sensor, infrared sensor, etc.

The processor 842 includes one or more processors. The processor includes, for example, a CPU, programmable circuitry, microprocessor, etc. In embodiments, the processors are dedicated to specific tasks, such as a graphic processor, a video processor, an image processor, a communication or baseband processor, an application processor etc. Additionally, in embodiments processing is accomplished, shared, or distributed between one or more processors. For example, an application processor may manage not only applications, but also BLUETOOTH and WI-FI communications. In embodiments, a codec is also provided for encoding and decoding digital data streams or signals. A codec may be integrated into one or more of the processors or may be stand alone. For example, a codec may be provided on the video processor, application processor or communication processor. The processor is configured to generate an image, determine the address of the individual pixels that are to be activated from the normally transparent mode when displaying the image and the amount of voltage necessary to achieve the desired color, color intensity, transparency or combinations thereof.

Memory 848 includes read only memory (ROM) and random access memory (RAM) in the form of one or more memory structures. Memory structures include, for example, NAND, SRAM, SDRAM, etc. In embodiments, memory is used to store the operating system, various applications, application framework or middleware, optional program modules, etc. Memory is also used as a buffer to store the image data after processing and prior to being displayed, such as in a frame buffer. In addition, or alternatively, the memory is configured to store data including measured relationships between the voltage and the permittivity for each adjustable permittivity material used in the device, which is retrieved by the processor to determine a voltage to apply to each pixel in a given image.

The photosensor 846 includes, for example, either a complimentary metal-oxide semiconductor (CMOS) or an active pixel sensor, or a charge coupled device (CCD). The photosensor is coupled either directly or through the serial bus to a processor, which manipulates the image, stores the images in memory, etc. In embodiments, a flash, shutter, or both are provided. In embodiments, the photosensor is used to determine the amount of ambient light, i.e., light surrounding the device. In embodiments, if insufficient ambient light is present, a backlight is turned on. Alternatively, or in addition, a different color model is selected to account for the reduction in ambient light. Furthermore, adjustments to the measured relationships between the material and voltage may be performed based on the amount of ambient light.

The power supply 850 includes, for example, one or more of a battery, a photovoltaic cell or a power supply cable as well as corresponding interfaces. Additionally, in embodiments, various transformers, alternating current to digital current converters, and other power management devices as well as, optionally, a power management processor are provided.

In accordance with the above, a method 900 of forming images on a display is illustrated in FIG. 9. An application, or other software, firmware or hardware generates an image to be viewed on the display 902. The image is divided into pixels and for each pixel a color and transparency level is determined by the processor 904. The pixel address of each pixel to be activated from the normally transparent mode is determined 906 by the processor. In addition, the voltage that will provide the desired mechanical strain on the adjustable permittivity material to achieve the color or degree of transparency is calculated 908 by the processor based on information stored in and retrieved from memory regarding the adjustable permittivity material. Then the voltage is applied to the adjustable permittivity material 910 to generate the image.

Any of the operations described herein may be implemented in a system that as alluded to above includes one or more tangible storage mediums having stored thereon, individually or in combination, instructions that when executed by one or more processors perform the methods described herein. Here, the processor may include, for example, a system CPU and/or other programmable circuitry. Also, it is intended that operations described herein may be distributed across a plurality of physical devices, such as processing structures at more than one different physical locations. The storage medium may include any type of tangible medium, for example, any type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, magnetic or optical cards, or any type of media suitable for storing electronic instructions. Other embodiments may be implemented as software modules executed by a programmable control device.

An aspect of the present disclosure relates to a transparent display device. The transparent display device includes a substrate, wherein the substrate allows greater than 50% of incident light to pass through the substrate. The device also includes a plurality of pixels formed on the substrate, wherein the pixels are formed of an adjustable permittivity material wherein the adjustable permittivity material exhibits a change in permittivity upon the application of a voltage and is normally transparent. The device further includes interconnects operatively coupled to the adjustable permittivity material in each pixel, wherein the interconnects are configured to provide voltage to the adjustable permittivity material.

In the above embodiment, the adjustable permittivity material includes a piezoelectric perovskite having the formula: ABO₃, wherein A is a cation of a first size S₁ and B is a cation of a second size S₂, which is smaller than the cation of A, and O is an anion that bonds to A and B. Further, in any of the above embodiments, the perovskite is doped. In addition, in any of the above embodiments the adjustable permittivity material is barium titanate. Alternatively, in any of the above embodiments is lead zirconate titanate. In addition, in any of the above embodiments, the substrate is flexible and exhibits a bending radius of 5 cm or less.

In any of the above embodiments, each of the pixels includes more than one pixel element and each of the pixel elements corresponds to a selected color in a color model. In any of the above embodiments, the color model is RGB color model and the pixels include three pixels elements. In any of the above embodiments, the display further comprises a color mask including a plurality of color locations that are registered with the pixel elements.

In any of the above embodiments, a supply electrode is connected to the adjustable permittivity material in each of the pixels and a drain electrode contacts the adjustable permittivity material of one or more of the pixels. In any of the above embodiments, a transistor coupled to each pixel. In any of the above embodiments, a protective layer covers the adjustable permittivity material.

In any of the above embodiments, the display is integrated into a mobile device. Alternatively, in any of the above embodiments the display is integrated into a display screen.

In another aspect the present disclosure relates to a method of forming a transparent display device as described in any of the above embodiments. The method includes forming a plurality of pixels on a substrate by depositing an adjustable permittivity material in discrete sections on the substrate wherein the substrate allows greater than 50% of incident light to pass through the substrate and the adjustable permittivity material is normally transparent. The method further includes depositing horizontal and vertical interconnects on the substrate, wherein the interconnects are operatively coupled to the adjustable permittivity material of the pixels.

In the above embodiment, the deposition of the adjustable permittivity material is performed by lithography. In any of the above embodiments, the deposition of the interconnects is performed by lithography. In any of the above embodiments, a supply electrode is deposited between the substrate and the adjustable permittivity material and a drain electrode is contacted with the adjustable permittivity material.

In any of the above embodiments, the adjustable permittivity material is a piezoelectric perovskite having the formula: ABO₃, wherein A is a cation of a first size S₁ and B is a cation of a second size S₂, which is smaller than the cation of A, and O is an anion that bonds to A and B. In any of the above embodiments the substrate is flexible and exhibits a bending radius of 5 cm or less. In any of the above embodiments, the pixels are formed from one or more elements, wherein each element is deposited on the substrate. In any of the above embodiments, a color mask overlies the elements.

In any of the above embodiments the adjustable permittivity material is covered with a protective layer.

In yet another aspect, the present disclosure relates to a method of forming an image on a transparent display as described and formed in any of the above embodiments. The method includes generating an image to be displayed on a transparent display with a processor, wherein the display allows greater than 50% of incident light having a wavelength in the range of 380 nm to 700 nm to pass through the display. In addition, the method includes dividing an image into pixels with the processor. Further, the method includes determining the color and transparency of each pixel by the processor and determining a voltage to apply to each of the pixels based on measured relationships of strain to permittivity for an adjustable permittivity material forming the pixels. The method also includes applying a voltage to the adjustable permittivity material of one or more of the pixels by the processor and altering the permittivity of the adjustable permittivity material.

In yet a further aspect, the present disclosure relates to a system of forming an image on a transparent display, comprising one or more storage mediums having stored thereon, individually or in combination, instructions that when executed by one or more processors result in the following operation of generating an image to be displayed on a transparent display with a processor, wherein the display allows greater than 50% of incident light having a wavelength in the range of 380 nm to 700 nm to pass through the substrate. The instructions further result in the operations of dividing an image into pixels with the processor, determining the color and transparency of each pixel by the processor, determining a voltage to apply to each of the pixels based on measured relationships of strain to permittivity for an adjustable permittivity material forming the pixels. The instructions further result in the operation applying a voltage to the adjustable permittivity material of one or more of the pixels by the processor and altering the permittivity of the adjustable permittivity material.

The foregoing description of several methods and embodiments has been presented for purposes of illustration. It is not intended to be exhaustive or to limit the claims to the precise steps and/or forms disclosed, and obviously many modifications and variations are possible in light of the above teaching. It is intended that the scope of the invention be defined by the claims appended hereto.

1. A transparent display device, comprising:
a substrate, wherein said substrate allows greater than 50% of incident light to pass through said substrate;
a plurality of pixels formed on said substrate, wherein said pixels are formed of an adjustable permittivity material wherein said adjustable permittivity material exhibits a change in permittivity upon the application of a voltage and is normally transparent; and
interconnects operatively coupled to said adjustable permittivity material in each pixel, wherein said interconnects are configured to provide said voltage to said adjustable permittivity material.

2. The transparent display device of claim 1, wherein said adjustable permittivity material includes a piezoelectric perovskite having the formula: ABO₃, wherein A is a cation of a first size S₁ and B is a cation of a second size S₂, which is smaller than the cation of A, and O is an anion that bonds to A and B.

3. The transparent display device of claim 1, wherein said perovskite is doped.

4. The transparent display device of claim 1, wherein said adjustable permittivity material comprises barium titanate.

5. The transparent display device of claim 1, wherein said adjustable permittivity material comprises lead zirconate titanate.

6. The transparent display device of claim 1, wherein said substrate is flexible and exhibits a bending radius of 5 cm or less.

7. The transparent display device of claim 1, wherein each of said pixels includes more than one pixel element and each of said pixel elements corresponds to a selected color in a color model.

8. The transparent display device of claim 1, wherein said color model is RGB color model and said pixels include three pixels elements.

9. The transparent display device of claim 8, wherein said display further comprises a color mask including a plurality of color locations that are registered with said pixel elements.

10. The transparent display device of claim 1, further comprising a supply electrode connected to the adjustable permittivity material in each of said pixels and a drain electrode contacting the adjustable permittivity material of one or more of said pixels.

11. The transparent display device of claim 10, further comprising a transistor coupled to each pixel.

12. The transparent display device of claim 1, further comprising a protective layer covering the adjustable permittivity material.

13. The transparent display device of claim 1, wherein said display is integrated into a mobile device.

14. The transparent display device of claim 1, wherein said display is integrated into a display screen.

15. A method of forming a transparent display device comprising:
forming a plurality of pixels on a substrate by depositing an adjustable permittivity material in discrete sections on said substrate wherein said substrate allows greater than 50% of incident light to pass through said substrate and said adjustable permittivity material is normally transparent;
depositing horizontal and vertical interconnects on said substrate, wherein said interconnects are operatively coupled to the adjustable permittivity material of said pixels.

16. The method of claim 15, wherein deposition of said adjustable permittivity material is performed by lithography.

17. The method of claim 15, wherein deposition of said interconnects is performed by lithography.

18. The method of claim 15, wherein said adjustable permittivity material is a piezoelectric perovskite having the formula: ABO₃, wherein A is a cation of a first size S₁ and B is a cation of a second size S₂, which is smaller than the cation of A, and O is an anion that bonds to A and B.

19. The method of claim 15, wherein said substrate is flexible and exhibits a bending radius of 5 cm or less.

20. The method of claim 15, wherein said pixels are formed from one or more elements, wherein each element is deposited on said substrate.

21. The method of claim 20, further comprising overlying said elements with a color mask.

22. The method of claim 15, further comprising depositing a supply electrode between the substrate and the adjustable permittivity material and contacting a drain electrode with said adjustable permittivity material.

23. The method of claim 15, further comprising covering said adjustable permittivity material with a protective layer.

24. A method of forming an image on a transparent display, comprising:
generating an image to be displayed on a transparent display with a processor, wherein said display allows greater than 50% of incident light having a wavelength in the range of 380 nm to 700 nm to pass through said display;
dividing an image into pixels with said processor;
determining the color and transparency of each pixel by said processor;
determining a voltage to apply to each of said pixels based on measured relationships of strain to permittivity for an adjustable permittivity material forming said pixels;
applying a voltage to the adjustable permittivity material of one or more of said pixels by said processor; and
altering the permittivity of said adjustable permittivity material.

25. A system of forming an image on a transparent display, comprising one or more storage mediums having stored thereon, individually or in combination, instructions that when executed by one or more processors result in the following operations comprising:
generating an image to be displayed on a transparent display with a processor, wherein said display allows greater than 50% of incident light having a wavelength in the range of 380 nm to 700 nm to pass through said display;
dividing an image into pixels with said processor;
determining the color and transparency of each pixel by said processor;
determining a voltage to apply to each of said pixels based on measured relationships of strain to permittivity for an adjustable permittivity material forming said pixels;
applying a voltage to the adjustable permittivity material of one or more of said pixels by said processor; and
altering the permittivity of said adjustable permittivity material.
